(19) United States
(12) Patent Application Publication
(10) Pub. No.: US 2010/0224955 A1
(43) Pub. Date: Sep. 9, 2010

(54) FUSES OF SEMICONDUCTOR DEVICE AND METHOD OF FORMING THE SAME

(75) Inventor: CHI HWAN JANG, ICHEON-SI (KR)

Correspondence Address: AMPACC Law Group, 3500 188th Street S.W., Suite 103, Lynnwood, WA, 98037, US

(73) Assignee: HYNIX SEMICONDUCTOR INC., ICHEON-SI (KR)

(21) Appl. No.: 12/648,262

(22) Filed: Dec. 28, 2009

(30) Foreign Application Priority Data
Mar. 9, 2009 (KR) 10-2009-0019891

(51) Int. Cl. H01L 23/525; H01L 21/768

(52) U.S. Cl. 257/529; 438/601; 257/734; 257/E23.149; 257/E21.592

(57) ABSTRACT

Devices and methods are disclosed a dielectric interlayer made of materials capable of forming tensile force is formed over a semiconductor substrate, and a fuse metal having stronger tensile force than the first dielectric interlayer is formed over the first dielectric interlayer. Accordingly, formation of fuse residues when blowing a fuse can be prevented. Furthermore, energy and a spot size of a laser applied when blowing a fuse can be reduced. Moreover, damage to neighboring fuses can be prevented, and a fuse made of materials that are difficult to blow the fuse can be cut. Further, since polymer-series materials are used as a dielectric interlayer, the coupling effect between wiring lines can be reduced considerably.

### CROSS-REFERENCE TO RELATED APPLICATION

The priority of Korean patent application No. 10-2009-0019891 filed Mar. 9, 2009, the disclosure of which is hereby incorporated in its entirety by reference, is claimed.

### BACKGROUND OF THE INVENTION

The present invention relates to a semiconductor device and a method of forming the same, and more particularly, to semiconductor fuses, which are capable of fundamentally preventing fuse residue from occurring when blowing a fuse.

Semiconductor devices, such as a memory device and memory merged logic (MML), each include numerous memory cells for storing data. If any one of the memory cells is faulty, a corresponding semiconductor device is determined to be faulty, resulting in a lowered yield. However, to discard the entire semiconductor device as being a faulty product although only some of the cells have failed is wasteful. Accordingly, a memory device or a semiconductor device including a large amount of memory requires a repair function in order to secure a high yield. The repair method in semiconductor devices is chiefly a method of replacing a memory cell array including a faulty memory cell with a redundant memory cell array. In order to replace the faulty memory cell array with the redundant memory cell array, fuses that can sever a line are used. Accordingly, a number of the fuses are used in the semiconductor device, and the fuses can be cut using a laser. These fuses are selectively cut according to the test results.

A repair method using a redundant cell uses a redundant word line for replacing a normal word line and a redundant bit line for replacing a normal bit line including a faulty cell. To this end, a memory device includes a circuit for replacing an address of the faulty cell to an address of the redundant cell when the faulty cell is detected through a test after wafer processing. Accordingly, if the cell address corresponding to the faulty cell is inputted when the memory device is used, data of the reserved cell that has replaced the faulty cell is accessed.

A typical repair method changes the path of an address by blowing a fuse using a laser beam. Accordingly, a typical memory device is manufactured with a fuse region for changing an address path by blowing a fuse using a laser. Here, a wiring line broken by the irradiation of the laser is called a fuse, and a region surrounding the fuse and its periphery is called a fuse box.

If residue is generated during blowing a fuse, a fail can occur because there may still be an electrical connection caused by the residue particles. Furthermore, if a larger spot size and/or higher energy laser is used, neighboring fuses can be cut. Accordingly, a problem arises because the yield of semiconductor devices is reduced.

### BRIEF SUMMARY OF THE INVENTION

An embodiment of the invention is directed to solving a problem which causes a fail occurring because a fuse is recognized as being connected due to fuse residues even though the fuse has been cut or cuts even neighboring fuses due to a large spot size and high energy of a laser applied to a fuse, by adopting a crack concept not a blowing concept when cutting a fuse of a semiconductor device using a laser.

According to an aspect of the present invention, a semiconductor device having a plurality of fuses comprise a first dielectric interlayer made of materials with a first tensile force, and a fuse metal formed over the first dielectric interlayer and configured to have a second tensile force greater than the first tensile force. Accordingly, since the dielectric interlayer causes tensile force in the fuse metal, a bare fuse can be formed by causing a crack in the fuse metal without blowing the fuse metal.

The fuse preferably further comprises a barrier metal layer formed between the first dielectric interlayer and the fuse metal and configured to control tensile force and the occurrence of a crack. Here, the barrier metal layer controls a state in which the crack is easily caused in the fuse metal through control of tensile force or high energy applied to cause the crack such that the crack is easily generated in the fuse metal with a laser of a small energy.

The barrier metal layer preferably is Ti, TiN, TaN, TaO₂, TiO₂, Ta, or a combination thereof.

The first dielectric interlayer preferably is made of oxide, nitride, carbon series, polymer-series materials, or a combination thereof. The above materials can easily control tensile force such that the crack is caused in the fuse metal.

The polymer-series materials preferably comprise polyimide, polypropylene, and polyvinyl chloride (PVC), or a combination thereof. Here, general polymer-series materials may be used. In particular, polyimide causes very strong tensile force in the fuse metal when the fuse metal is made of copper (Cu). Thus, a crack can be easily caused in the fuse metal even by small laser energy.

The fuse preferably further comprises a second dielectric interlayer formed on the fuse metal. This construction further includes a normal fuse construction in which the second dielectric interlayer is further formed on the fuse metal.

The fuse preferably further comprises a barrier metal layer formed between the fuse metal and the second dielectric interlayer and configured to control tensile force and the occurrence of a crack. Here, the barrier metal layer controls a state in which the crack is easily caused in the fuse metal through control of tensile force or high energy applied to cause the crack such that the crack is easily generated in the fuse metal with a laser of a small energy.

The barrier metal layer preferably is Ti, TiN, TaN, TaO₂, TiO₂, Ta, or a combination thereof.

The second dielectric interlayer preferably is made of oxide, nitride, carbon series, polymer-series materials, or a combination thereof. The above materials can easily control tensile force such that the crack is caused in the fuse metal.

The fuse metal preferably is made of Cu, Ag, Al, Au, Pt, poly, or a combination thereof.

According to another aspect of the present invention, a method of forming fuses of a semiconductor device comprises forming a first dielectric interlayer made of materials with a first tensile force over a semiconductor substrate and forming a fuse metal having a second tensile force greater than the first tensile force over the first dielectric interlayer.

The method preferably further comprises, after forming the first dielectric interlayer, forming a barrier metal layer to control tensile force and the occurrence of a crack over the first dielectric interlayer.

The forming-a-barrier-metal-layer or a-fuse-metal preferably is performed using any one of a chemical vapor deposition (CVD) method, an electric furnace method, or a physical vapor deposition (PVD) method.

The forming-a-barrier-metal-layer or a-fuse-metal preferably is performed in a temperature range between 0° C. and 700° C. The reason why the temperature is limited is that, at a temperature more than 700° C., the polymer-series materials used as the first dielectric interlayer or the second dielectric interlayer are melted.

The method preferably further comprises, after forming the fuse metal, forming a second dielectric interlayer on the fuse metal.

The method preferably further comprises, after forming the fuse metal, forming a barrier metal layer to control tensile force and the occurrence of a crack over the fuse metal.

The forming a-barrier-metal-layer or a-fuse-metal preferably is performed using any one of a CVD method, an electric furnace, or a PVD method.

The forming-a-barrier-metal-layer or a-fuse-metal preferably is performed in a temperature range of normal temperature normal temperature between 0° C. and 700° C. The reason why the temperature is limited is that, at a temperature more than 700° C., the polymer-series materials used as the first dielectric interlayer or the second dielectric interlayer are melted.

Advantages of the preferred embodiment may include one or more of the following. Formation of fuse residues when blowing a fuse can be prevented. Furthermore, energy and a spot size of a laser applied when blowing a fuse can be reduced. Moreover, damage to neighboring fuses can be prevented, and a fuse made of materials that are difficult to blow the fuse can be cut. Further, since polymer-series materials are used as a dielectric interlayer, the coupling effect between wiring lines can be reduced significantly.

### BRIEF DESCRIPTION OF THE DRAWINGS

FIG. 1 is a cross-sectional view of a fuse according to an embodiment of the present invention; and

FIG. 2 is a plan view of the fuse according to an embodiment of the present invention.

### DESCRIPTION OF EMBODIMENTS

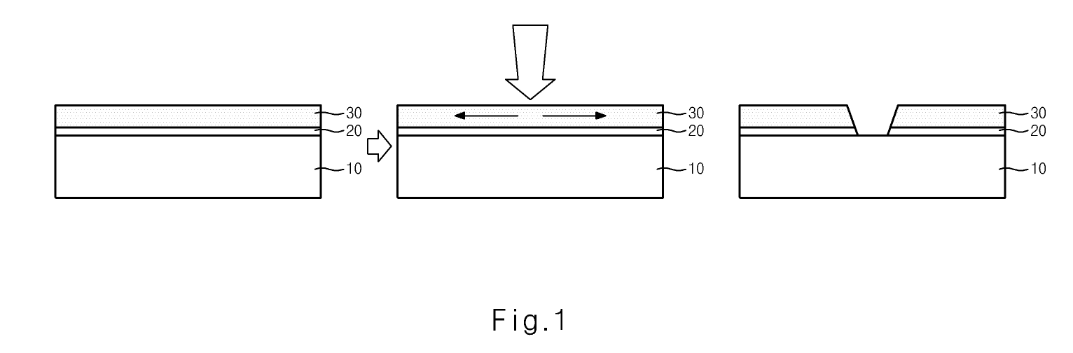

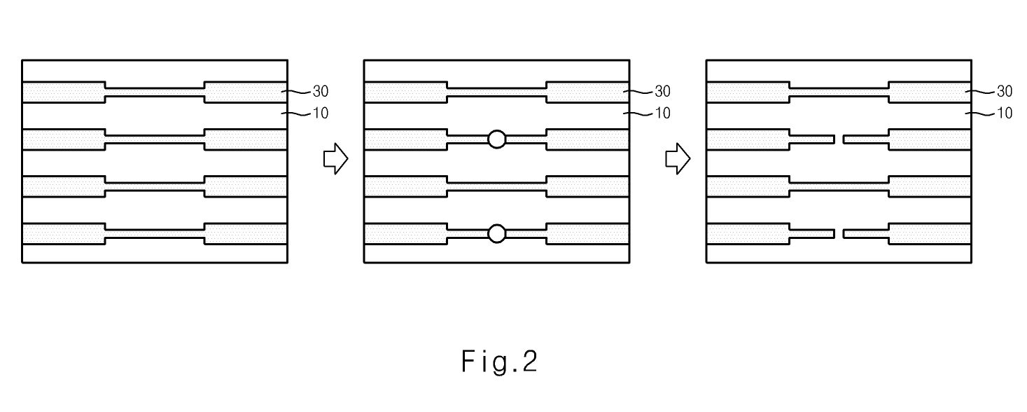

FIGS. 1 and 2 are a cross-sectional view and a plan view of a fuse according to an embodiment of the present invention.

It is to be noted that, although only one fuse element is illustrated in FIG. 1 and described, a number of the fuse elements are arranged as shown in FIG. 2. In more detail, a memory cell array (not shown), a redundant memory cell array (not shown) for replacing a faulty memory cell of the memory cell array, and a number of fuse elements for blocking a path to the faulty memory cell and inputting and outputting data to and from a corresponding redundant memory cell are arranged.

As shown in FIG. 1, the fuses of a semiconductor device according to the embodiment of the present invention each include a dielectric interlayer 10, a barrier metal layer 20, and a fuse metal 30. Although not shown in FIG. 1, another dielectric interlayer (not shown) may be further formed on the fuse metal 30. Hereinafter, an exposed fuse as shown in FIG. 1 is described as an example.

The dielectric interlayer 10 may be made of materials that are able to form a tensile force in the barrier metal layer 20 or the fuse metal 30. More particularly, the materials may include oxide, nitride, carbon series, and polymer-series materials. The polymer-series materials include polypropylene, polyvinyl chloride (PVC), and polyimide. It is to be noted that the dielectric interlayer 10 is not limited to the above-described materials, but may include any materials that are able to a form tensile force in the fuse metal 30.

Furthermore, the dielectric interlayer 10 may be deposited using a method, such as a chemical vapor deposition (CVD) method, an electric furnace method, a physical vapor deposition (PVD) method, and a spin-coating method. The dielectric interlayer 10 formed using the above method gives tensile force to the barrier metal layer 20 and the fuse metal 30. Thus, although only small energy laser treatment is applied to the fuse metal 30 and the dielectric interlayer 10, tensile stress applied to the fuse metal 30 can be mitigated by cracking in the fuse metal 30, thereby cutting a fuse. That is, dislocation and roughness are formed in the fuse metal 30 through laser treatment so that the fuse is cut. Here, the crack of the fuse metal 30 can be generated by a method using an ion beam or performing thermal treatment after nano-probing as well as the method using a laser.

The barrier metal layer 20 and the fuse metal 30 are formed over the dielectric interlayer 10 and are manufactured to have a tensile force. In order to further increase the tensile force, the barrier metal layer 20 and the fuse metal 30 may be deposited using a method, such as a CVD method, an electric furnace method, or a PVD method, at a deposition temperature of about 0° C. to 700° C. The barrier metal layer 20 and the fuse metal 30 may be formed at the deposition temperature of 700° C. or less because, at a temperature of more than 700° C., polymer-series materials used as the dielectric interlayer 10 will melt.

In the case where the dielectric interlayer 10 is made of materials that are difficult to blow the barrier metal layer 20 and the fuse metal 30, a damascene process can be performed such that the dielectric interlayer 10 surrounds the barrier metal layer 20 and the fuse metal 30 to thereby increase tensile force applied to the barrier metal layer 20 and the fuse metal 30. The barrier metal layer 20 may be made of any one of Ti, TiN, TaN, TaO₂, TiO₂, Ta, and a combination of them, the fuse metal 30 may be made of any one of Cu, Ag, Al, Au, Pt, poly, and a combination of them.

Furthermore, the barrier metal layer 20 functions to control the tensile force applied to the fuse metal 30 formed over the dielectric interlayer 10. For example, when the size of a lattice of atoms forming the fuse metal 30 is smaller than the size of a lattice of atoms forming the dielectric interlayer 10, the atoms of the fuse metal 30 attempt to stably couple with the atoms of the dielectric interlayer 10 by widening a gap therebetween. Accordingly, although energy is not applied to the fuse metal 30, the fuse metal 30 has enough tensile stress so that a crack can be generated in the fuse metal 30. However, when the size of a lattice of the atoms forming the fuse metal 30 is larger than the size of a lattice of the atoms forming the dielectric interlayer 10, the atoms of the fuse metal 30 attempt to stably couple with the atoms of the dielectric interlayer 10 by narrowing a gap therebetween. Thus, although high energy is applied to the fuse metal 30, compressive stress is applied to the fuse metal 30 to the extent that a fuse is not cut. Accordingly, the barrier metal layer 20 functions to lower tensile force and stress that are generated by a difference in the size of a lattice of atoms forming the dielectric interlayer 10 and the fuse metal 30. In more detail, in the case where tensile force has been formed in the fuse metal 30, the barrier metal layer 20 composed of atoms each having a size that is half the size of a lattice of atoms forming the dielectric interlayer 10 and the fuse metal 30 is disposed between the dielectric interlayer 10 and the fuse metal 30. On the other hand, in the case where stress has been formed in the fuse metal 30, the barrier metal layer 20 composed of atoms each having a size that is larger than the size of a lattice of atoms forming the fuse metal 30 is disposed between the dielectric interlayer 10 and the fuse metal 30. Accordingly, the occurrence of a crack in the fuse metal 30 can occur because of too strong tensile force, or the fuse metal 30 can be prevented from being cut by laser treatment because of compressive stress formed in the fuse metal 30.

For example, in the case where polymer-series polyimide is deposited as the dielectric interlayer 10 and the fuse metal 30 made of copper (Cu) is deposited over the dielectric interlayer 10, although energy is not applied to the fuse metal 30, copper (Cu) can be deposited with very strong tensile force such that a crack is caused in the fuse metal 30. The barrier metal layer 20 between the dielectric interlayer 10 and the fuse metal 30 functions to prevent a crack from occurring in the fuse metal 30 made of copper (Cu) but allows a crack to form in the fuse metal 30 through laser treatment of a low energy.

As shown in FIG. 2, regions in which the fuse metals 30 will be cut may be patterned to have a narrow width. The width of the fuse metal 30 is narrowly formed so that the fuse metal 30 can be easily cut. Here, the cutting of the fuse metal 30 is not based on a known blowing concept, but on a crack concept. Accordingly, only a desired fuse metal 30 can be easily cut using only laser treatment of a small energy without using a laser of a great energy and a wide laser spot region which are required for blowing. Furthermore, fuse metals neighboring a fuse metal 30 to be cut are not damaged.

A crack generated on a surface of the fuse metal 30 can be caused by mitigating the tensile force of the fuse metal 30 using energy smaller than the energy needed for the conventional blowing method and thus forming a potential on the surface of the fuse metal 30. Here, the energy of the laser preferably ranges from 0.001 J to 0.1 J.

Thus, a problem that residues are generated in the fuse metal 30 when cutting a fuse can be prevented. Further, damage to neighboring fuse metals can be effectively reduced, and a fail resulting from such damage can be reduced.

The fuses of a semiconductor device, and the method of forming the same have the following advantages.

First, the formation of fuse residues when blowing the fuse can be fundamentally prevented.

Second, damage to neighboring fuses can be prevented through only laser treatment.

Third, energy and a spot size of a laser applied when blowing a fuse can be reduced because the crack principle is used.

Fourth, a fuse made of material that is difficult to use for fuse blowing can be cut.

Fifth, since the dielectric interlayer is made of polymer-series materials, a coupling effect between wiring lines can be reduced to the extreme extent, and the occurrence of a crack can be prevented.

Sixth, the present invention can also be applied to the existing laser cutting system.

The above embodiment of the present invention is illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non-volatile memory device. Other additions, subtractions, or modifications are obvious in view of the present disclosure and are intended to fall within the scope of the appended claims.

What is claimed is:

1. A semiconductor device having a plurality of fuses, each fuse comprising:
a first dielectric interlayer made of materials with a first tensile force; and
a fuse metal formed over the first dielectric interlayer and configured to have a second tensile force greater than the first tensile force.

2. The semiconductor device according to claim 1, wherein each fuse further comprising a barrier metal layer formed between the first dielectric interlayer and the fuse metal and configured to control a tensile force and an occurrence of a crack.

3. The semiconductor device according to claim 2, wherein the barrier metal layer comprises Ti, TiN, TaN, TaO₂, TiO₂, Ta, or a combination thereof.

4. The semiconductor device according to claim 1, wherein the first dielectric interlayer comprises oxide, nitride, carbon series, polymer-series materials, or a combination thereof.

5. The semiconductor device according to claim 4, wherein the polymer-series materials further comprise polyimide, polypropylene, polyvinyl chloride (PVC), or a combination thereof.

6. The semiconductor device according to claim 1, each fuse further comprising a second dielectric interlayer formed on the fuse metal.

7. The semiconductor device according to claim 6, each fuse further comprising a barrier metal layer formed between the fuse metal and the second dielectric interlayer and configured to control a tensile force and an occurrence of a crack.

8. The semiconductor device according to claim 7, wherein the barrier metal layer comprises Ti, TiN, TaN, TaO₂, TiO₂, Ta or a combination thereof.

9. The semiconductor device according to claim 6, wherein the second dielectric interlayer comprises oxide, nitride, carbon series, polymer-series materials or a combination thereof.

10. The semiconductor device according to claim 9, wherein the polymer-series materials comprise polyimide, polypropylene, PVC, or a combination thereof.

11. The semiconductor device according to claim 1, wherein the fuse metal comprises Cu, Ag, Al, Au, Pt, poly, or a combination thereof.

12. A method for forming fuses in a semiconductor device, comprising:
forming a first dielectric interlayer made of materials with a first tensile force over a semiconductor substrate; and
forming a fuse metal having a second tensile force greater than the first tensile force over the first dielectric interlayer.

13. The method according to claim 12, further comprising, after forming the first dielectric interlayer, forming a barrier metal layer to control a tensile force and an occurrence of a crack over the first dielectric interlayer.

14. The method according to claim 13, wherein the forming-a-barrier-metal-layer or a-fuse-metal is performed using a chemical vapor deposition (CVD) method, an electric furnace method, or a physical vapor deposition (PVD) method.

15. The method according to claim 13, wherein the forming-a-barrier-metal-layer or a-fuse-metal is performed in a temperature range between about 0° C. and 700° C.

16. The method according to claim 12, further comprising forming a second dielectric interlayer on the fuse metal.

17. The method according to claim 16, further comprising, after forming the fuse metal, forming a barrier metal layer to control a tensile force and an occurrence of a crack over the fuse metal.

18. The method according to claim 17, wherein the forming a-barrier-metal-layer or a-fuse-metal is performed using a CVD method, an electric furnace, or a PVD method.

19. The method according to claim 17, wherein the forming-a-barrier-metal-layer or a-fuse-metal is performed in a temperature range between about 0° C. and 700° C.
